(19) United States
(12) Patent Application Publication
(10) Pub. No.: US 2003/0189202 A1
(43) Pub. Date: Oct. 9, 2003

(54) Nanowire devices and methods of fabrication

(76) Inventors: Jun Li, Sunnyvale, CA (US); Jie Han, Cupertino, CA (US); Alan M. Cassell, San Jose, CA (US)

Correspondence Address: FISH & NEAVE, 1251 AVENUE OF THE AMERICAS, 50TH FLOOR, NEW YORK, NY, 10020-1105, US

(21) Appl. No.: 10/117,965

(22) Filed: Apr. 5, 2002

(51) Int. Cl. H01L 29/06; H01L 31/0328; H01L 31/0336; H01L 31/072; H01L 31/109

(52) U.S. Cl. 257/14

(57) ABSTRACT

Nanowire devices are provided based on carbon nanotubes or single-crystal semiconductor nanowires. The nanowire devices may be formed on a silicon substrate or other suitable substrate. Electrodes may be patterned on the substrate. Catalyst sites may be formed on the electrodes prior to nanowire growth. Chemical vapor deposition techniques may be used to grow the nanowires at the catalyst sites. A material such as an insulator may be formed on the nanowires following nanowire growth. The insulator may be planarized using chemical-mechanical polishing or other suitable techniques. The resulting nanowire device may be used in chemical or biological sensors, as a field emitter for displays, or for other applications.

### STATEMENT OF GOVERNMENT SUPPORT

This invention was made in the course of U.S. contract No. NAS2-99092 awarded by NASA. The U.S. government has certain rights in the invention.

### BACKGROUND OF THE INVENTION

This invention relates to nanowires and more particularly, to nanowire devices and methods for forming nanowire devices.

Nanowires are of interest for forming chemical or biological sensors, field emitters for flat panel displays, and other devices. Nanowires such as carbon nanotubes may be metallic or semiconducting in nature. Single-crystal semiconductor nanowires and nanowires made of other substances may also be grown. A typical nanowire may have a diameter on the order of 2-100 nm and a length of 0.5-10 μm.

The growth of nanowires has been demonstrated experimentally, but improved techniques for forming devices based on nanowires for applications such a field emitters and sensors and other applications are needed.

It is therefore an object of the present invention to provide improved nanowire devices and improved ways in which to form such nanowire devices.

### SUMMARY OF THE INVENTION

Nanowire devices and methods for fabricating such devices are provided. Nanowires may be formed on substrates such as silicon, quartz, glass, or other suitable substrate materials. An electrode layer may be formed on the substrate. The electrode layer may, for example, be formed of titanium, gold, platinum, molybdenum, chromium, or other metals or conductive materials. The electrode layer may be patterned. For example, photolithographic techniques may be used to pattern the electrode layer into an array of pads that may be individually addressed electronically.

A catalyst may be used to seed the growth of nanowires on the pads. Catalyst sites may be randomly distributed on the electrode pads or may be purposefully distributed in a known pattern. A known pattern of “dots” of catalyst may, for example, be used to form a regular array of nanowires with a desired spacing between nanowires and desired wire diameters.

Nanowires may be grown on the catalyst sites by known growth techniques such as thermal or plasma chemical vapor deposition (CVD) techniques or other suitable nanowire growth techniques. Any suitable nanowires may be grown, including single-walled or multiple-walled carbon nanotubes, single-crystal semiconductor nanowires, carbon nanofibers (either solid rods or tubes with amorphous walls or graphitic cylindrical walls not perfectly parallel to the axis of the tube), metal nanowires (e.g., tungsten nanowires, molybdenum nanowires, etc.), and nanowires of inorganic compound materials (such as ZnO).

Typical catalysts for nanowire growth include metals such as nickel, cobalt, and iron (to catalyze growth of nanowires such as carbon nanotubes) or gold or zinc (to catalyze growth of single-crystal semiconductor nanowires). Non-catalytic nanowire growth techniques may be used if desired, but are generally not preferred due to the difficulty of controlling nanowire growth parameters in the absence of catalyst.

After nanowire growth additional materials may be deposited on the nanowires. A dielectric layer may be deposited. For example, an oxide layer such as a silicon dioxide layer deposited using tetraethylorthosilicate (TEOS) chemical vapor deposition (CVD) may be formed on the nanowires. Other dielectric materials that may be deposited or grown on the nanowires include polymers, glasses (e.g., spin-on glasses), nitride, and salts such as CaF₂. The additional material layer (or layers) formed on the nanowires may fill all or at least some of the volume between adjacent nanowires and may therefore help to increase the mechanical strength of the nanowires and electrically insulate the nanowires from each other. The additional material layer may also have desired optical properties (e.g., a desired index of refraction).

In general, the insulated or coated nanowires will not initially have a planar morphology, due to natural variations in the growth rate of the nanowires and coating across the substrate. The nanowire structures may be planarized to create a flat morphology. Suitable planarization techniques include material removal techniques such as chemical-mechanical polishing (CMP), mechanical polishing, and chemical etching. Certain insulating materials such as spin-on glasses may also be used to help planarize the substrate. After the nanowire devices are planarized, the tips of the nanowires are exposed, because they are located at the planarized surface of the structure (e.g., the tips are in the plane of the planarized insulator or other planarized coating or the tips protrude slightly out of this plane by a few to hundreds of nanometers).

The planarized nanowire devices may be used for a variety of applications, such as sensor and field emitter applications. If desired, additional processing steps may be used to customize the planarized nanowire devices for particular applications. For example, additional material layers may be deposited on the devices and additional patterning steps may be performed. The substrate may be diced into individual die, each of which contains a portion of the nanowire structures formed on the substrate. The die may be packaged in suitable packages and may be interconnected with circuitry and other devices.

Further features of the invention, its nature and various advantages will be more apparent from the accompanying drawings and the following detailed description.

### BRIEF DESCRIPTION OF THE DRAWINGS

FIG. 1 is a schematic diagram of an illustrative substrate wafer having a plurality of nanowire devices in accordance with the present invention.

FIG. 2a is a schematic diagram showing an illustrative nanowire device that has a plurality of electrodes each of which has a plurality of catalyst sites in accordance with the present invention.

FIG. 2b is a schematic diagram showing an illustrative nanowire device that has a plurality of line-shaped electrodes each of which has a plurality of catalyst sites in accordance with the present invention.

FIG. 3 is a schematic diagram of illustrative fabrication tools that may be used in forming nanowire devices in accordance with the present invention.

FIGS. 4a-4f are schematic diagrams showing cross-sectional side views of an illustrative nanowire device during illustrative fabrication steps in accordance with the present invention.

FIG. 5 is a flow chart showing illustrative steps involved in fabricating illustrative nanowire devices in accordance with the present invention.

FIG. 6 is a more generalized flow chart showing illustrative steps involved in fabricating nanowire devices in accordance with the present invention.

### DETAILED DESCRIPTION

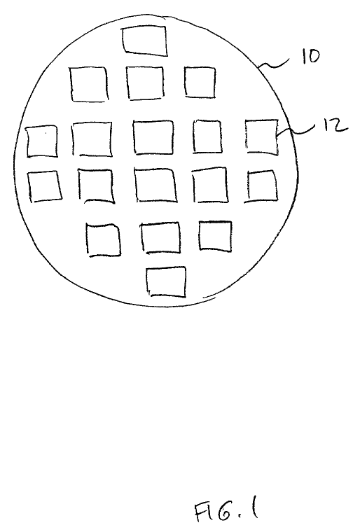

An illustrative substrate 10 on which a plurality of nanowire devices 12 have been formed is shown in FIG. 1. One suitable substrate material is silicon, because silicon wafers are readily available from sources supplying the semiconductor industry. A typical silicon wafer may be a standard 12″ wafer or a wafer of 25 to 30 centimeters in diameter and may have a thickness on the order of 1 mm. Other suitable substrates include other semiconductors, quartz, sapphire, and glass. These are merely illustrative examples. Any suitable substrate material may be used if desired. Moreover, although substrate 10 is shown as being round in the plan view of FIG. 1, substrate 10 may be any suitable shape. For example, substrate 10 may be square or rectangular.

The devices 12 are shown being disposed in a regular pattern of rows and columns. This type of pattern may be advantageous if it is desired to dice or separate individual devices 12 for packaging at the end of the fabrication process, but other patterns of devices 12 may be used.

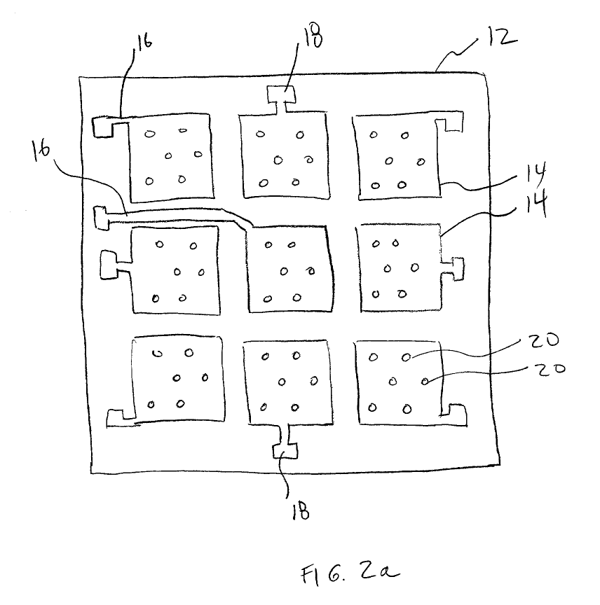

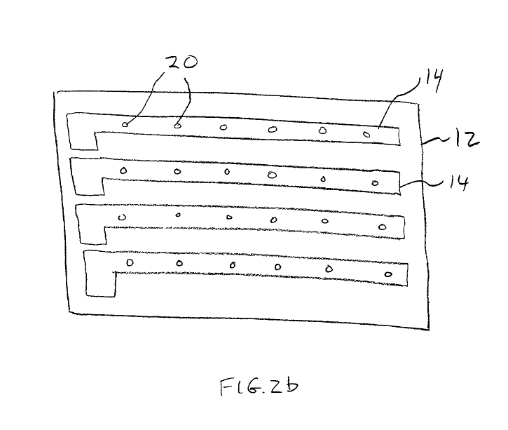

An illustrative nanowire device 12 is shown in FIG. 2a. Device 12 of FIG. 2a is shown as having a plurality of electrodes 14. These electrodes or pads are preferably formed of a conducting substance such as a metal. Suitable metals for pads 14 include titanium, gold, platinum, molybdenum, and chromium. These are merely illustrative examples of pad metals that may be used. In general, electrodes 14 may be formed of any suitable metal. Metal alloys may be used or layers of different metals may be used (e.g., to promote adhesion with substrate 10).

In FIG. 2a, electrodes 14 are shown as being arranged in a regular array of rows and columns. This is merely illustrative. Electrodes 14 may be any suitable shape and may be arranged in any suitable pattern on substrate 10. For example, electrodes 14 may be triangular in shape or may be formed in the shape of hexagons, octagons, circles, ovals, lines, etc. Electrodes that are provided in the form of cells or pads may be individually addressable as shown in FIG. 2a. If desired, line-shaped electrodes may be used. The specific shapes for electrodes 14 and the specific pattern in which electrodes 14 are arranged may be determined by the ultimate application for which devices 12 are to be used. For example, in some applications it may be desirable for each electrode 14 to be regularly spaced from the other in well-aligned rows and columns. If devices 12 are to be used as part of a chemical or biological sensor, groups of electrodes 14 may be used that may be (but need not be) arranged in rows and columns.

Electrodes 14 may be interconnected using interconnects such as interconnect 16. The interconnects may connect the main pad portions of electrodes 14 to bonding pads 18 or to other circuitry or contact regions on device 12. If bonding pads 18 are used, such pads may be electrically connected to the leads in a circuit package using wire bonding equipment or using the flip-chip solder ball mounting technique. These are merely illustrative techniques for electrically connecting electrodes 14 with other circuitry. Any suitable arrangement may be used if desired. Although a plurality of electrodes 14 are shown in the example of FIG. 2a, there may be only one electrode 14 associated with each device 12. Nine electrodes 14 are shown in FIG. 2a, but there may be fewer than nine electrodes, nine or more electrodes, or hundreds, thousands, tens of thousands, hundreds of thousands, or more of electrodes 14 if desired.

Electrodes 14 may be on the order of several microns in size. For example, the lateral dimension of electrodes 14 (i.e., the length of a side of the square or the diameter of a circle) may be in the range of 100 nm to 1000 μm, may be in the range of 0.1 to 10 μm, may be in the range of 5 to 100 μm, may be more than 5 μm, or may be in the range of 0.2 to 20 μm. These are merely illustrative dimensions. The appropriate size of electrodes 14 will typically be determined by the desired end use of device 12. For example, if the end use of device 12 is a display device, electrodes 14 may be the size of the pixel size in the display. If the end use of device 12 is as a biological sensor, the appropriate size and arrangement of electrodes 14 may be determined by the type of biological specimen that is being detected.

As shown in FIG. 2a, one or more catalyst sites 20 may be provided on each electrode 14. Typical catalysts for nanowire growth include metals such as nickel, cobalt, and iron (to catalyze growth of nanowires such as carbon nanotubes) or gold or zinc (to catalyze growth of single-crystal semiconductor nanowires). Non-catalytic nanowire growth techniques may be used if desired, but are generally not preferred due to the difficulty of controlling nanowire growth parameters in the absence of catalyst.

Catalyst sites 20 may be formed using any suitable technique. For example, e-beam lithography and metallic catalyst deposition techniques may be used to form catalyst sites 20. Other suitable catalyst site formation techniques that may be used include techniques based on heating deposited metal so that it collects into discrete metal areas (“metal migration“), heat-collapsible porous polymer balls filed with metal salts, techniques in which metal is evaporated through a thin film assembly of microscopic balls (e.g., balls 100 nm to 100 μm in diameter) that have been temporarily placed on the electrode surface, lithographic techniques (e.g., standard ultraviolet (UV) lithography, deep UV (DUV) lithography, extreme UV (EUV) lithography, etc.), X-ray or ion beam lithography, electrochemical deposition, electroless deposition, or soft lithography (e.g., when a damp “stamp” is used to impress a pattern of catalytic “ink” on a substrate), etc. Techniques such as these are described further in the commonly-assigned concurrently-filed copending patent application entitled “Catalyst Patterning for Nanowire Devices,” (Attorney Docket No. INI-7), Serial No. ______, which is hereby incorporated by reference herein in its entirety.

As shown in FIG. 2b, electrodes 14 may be formed in the shape of lines. Lines 14 may be, for example, several microns in width and many centimeters in length. This type of geometry may be useful when it is desired to cover large portions or lengths of a device using a single electrode.

In the examples of FIGS. 2a and 2b, catalyst sites 20 are shown as being spaced at fairly regular intervals. This is merely illustrative. Catalyst sites 20 may be placed wherever needed for a particular nanowire device application. An advantage of using regular (non-random) patterns such as grids or arrays is that such an approach may help to ensure that the behavior of the nanowire device is well controlled.

Nanowire diameters are typically on the order of 10 nm to 100 nm. Accordingly, catalyst sites 20 typically have lateral dimensions 20 on the order of 10 nm to 100 nm, although sites with other suitable dimensions (e.g., 5 to 200 nm) may be used if desired.

The density of the catalyst sites that is used depends on the desired density of nanowires to be grown. A wide range of nanowire densities may be used. For example, densities may range from 1/cm² to 10¹¹/cm² or more, from 10³/cm² to 10⁹/cm², etc. Any density of nanowires within these illustrative ranges or any other suitable density of nanowires may be produced by patterning catalyst sites 20 appropriately. There may be one catalyst site 20 and therefore one nanowire per electrode 14, 1-100 sites and wires per electrode, 10²-10³ sites and wires per electrode, more than 10³ sites and wires per electrode, or 10³-10¹¹ or more sites and wires per electrode if desired.

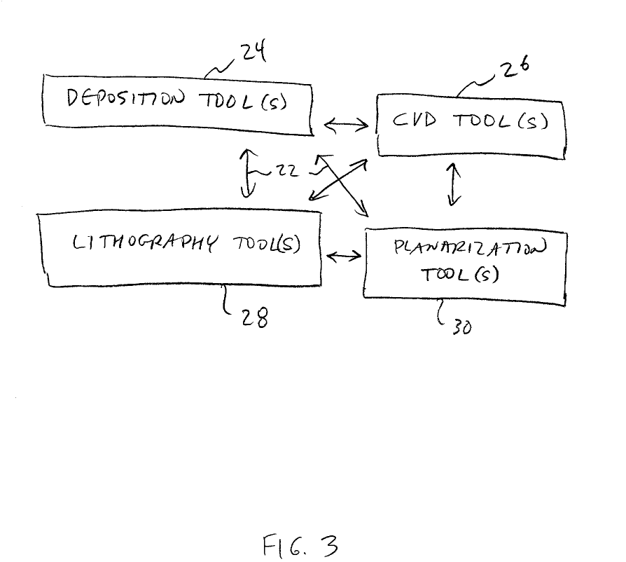

Illustrative fabrication tools that may be used in forming nanowire devices 12 are shown in FIG. 3. The various lines 22 between the tools of FIG. 3 illustrate schematically how the substrate or wafer on which the nanowire devices are being formed may be passed between tools during a typical fabrication process. For example, one or more deposition tools 24 may be used to form the metal layers for both the electrodes or pads 14 and catalyst sites or areas 20.

Deposition tools 24 may include evaporators, sputterers, or plasma-enhanced deposition tools (e.g., for depositing metal layers or for depositing oxide layers such as TEOS CVD silicon dioxide layers), sprayers or other coating equipment (e.g., for depositing spin-on glasses or polymers such as polyimide), furnaces or ovens for depositing or growing layers of materials such as oxides and nitrides, etc. These are merely illustrative deposition tools 24. Any suitable deposition tools may be used to deposit materials on wafer 10 and devices 12 during fabrication if desired.

Chemical vapor deposition (CVD) tools 26 may include thermal chemical vapor deposition equipment, plasma-enhanced vapor deposition equipment, or any other suitable material for growing material layers (e.g., oxides layers) and nanowires on substrate 10. The feedstock or precursors used in the CVD tools 26 is determined by the type of nanowire or material layer to be grown. For example, organometallic compounds or precursors such as silane or silicon tetrachloride or other vapor precursors may be used to grow single-crystal semiconductor nanowires (e.g., silicon nanowires, zinc oxide nanowires, germanium phosphate nanowires, indium phosphide nanowires, other II-VI semiconductor nanowires, III-V semiconductor nanowires, etc.) Feedstock such as methane, ethylene, acetylene, benzene, or other small hydrocarbon gasses or vapors may be used to grow single-walled and multiple-walled carbon nanotubes.

During plasma CVD growth, the inherent electric field produced by the plasma may help to vertically orient the nanowires that are grown. An external electric field may also be applied to a plasma or thermal CVD growth chamber to enhance the uniformity (e.g., the verticality) of the nanowire alignment. A typical electric field strength that may be used to enhance nanowire alignment may be on the order of 100-1000 V/cm.

Dopants such as nitrogen, oxygen, or phosphorous may be incorporated into single-crystal semiconductor nanowires by introducing dopant gasses during nanowire growth or by using any other suitable doping technique. Doped nanowires may be more conductive than undoped semiconducting nanowires, which may be advantageous when the nanowires are used as conductors in finished nanowire devices.

Lithography tools 28 may be used to pattern electrodes 14 and catalyst sites 20 (when lithographic techniques are used to form such patterns and sites). Tools 28 may include UV, DUV, or EUV lithography mask aligners or steppers, may include e-beam lithography tools or ion-beam or X-ray lithography tools. Tools 28 may include shadow masking equipment for forming electrodes 14 using shadow masking techniques. Tools 28 may also include the spinning or spraying or other coating tools used to coat photoresist onto substrate 10 and the tools necessary to develop and clean photoresist once exposed or used in a patterning step. Tools 28 may also include tools for wet and dry etching (e.g., tools to etch metals and oxides that have been patterned with photoresist or oxide or other materials).

It may be desirable to planarize the nanowire structures that are formed. Suitable planarization tools 30 include tools for chemical-mechanical polishing (CMP), tools for mechanical polishing (e.g., lapping and grinding machines that use mechanical polishing substances rather than chemical polishing substances), and tools for planar etching (e.g., wet chemical etch tools and dry etchers such as plasma or reactive ion etchers (RIE) tools). Planarization tools 30 may also include tools for applying materials such as spin-on glasses that have planarizing properties.

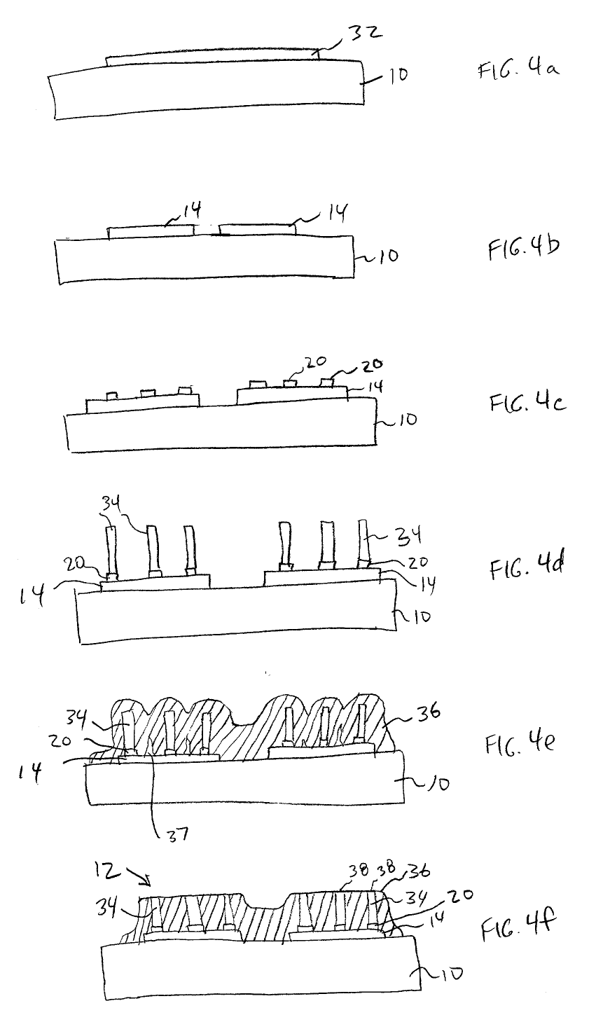

The drawings of FIGS. 4a to 4f show a cross-section (not to scale) of an illustrative portion of a substrate 10 during steps involved in fabricating an illustrative nanowire device 12.

After wafer preparation (e.g., cleaning by, for example, oxide growth and a cleaning hydrofluoric acid etch in the case of a silicon substrate) or after a layer of oxide or other suitable foundational surface layer has been grown (e.g., in the case of a silicon wafer substrate), a layer of metal 32 may be formed on substrate 10, as shown in FIG. 4a. As an example, a layer of titanium, gold, or platinum may be evaporated onto substrate 10. Suitable adhesion metal layers may be used to enhance the adhesion of metal 32 to substrate 10 if desired. Metal alloys may also be deposited as layer 32 if desired. Although a metal layer is preferred, there may be certain applications where other suitable conductors (e.g., doped polysilicon layers) may be used in place of metal. Metal 32 is merely illustrative. Deposition tools 24 of FIG. 3 may be used to form layer 32.

Electrode pads may be formed by patterning metal 32. For example, a shadow mask may be used during deposition to pattern metal 32 or lithography tools may be used to pattern metal 32 into electrodes 14, as shown in FIG. 4b. After patterning metal layer 32 to form electrode pads 14, catalyst sites 20 may be formed on electrodes 14, as shown in FIG. 4c. The catalyst sites 20 may, for example, be formed using e-beam lithography, UV lithography, or any other suitable catalyst patterning technique.

As shown in FIG. 4d, after the catalyst sites 20 have been formed, nanowires 34 may be grown on catalyst sites 20 (e.g., using thermal chemical vapor deposition, plasma-enhanced chemical vapor deposition, or any other suitable nanowire growth technique). The uniform alignment of the nanowires (e.g., all nanowires being vertical in the orientation of the example of FIG. 4d), may be enhanced during nanowire growth by use of an electric field.

As shown in FIG. 4e, after the nanowires 34 have been grown, a layer of material 36 (e.g., an electrical insulator such as silicon dioxide or a polymer or spin-on glass) may be formed on the top of the structures on substrate 10. If desired, layer 36 may be formed from a number of different materials.

Layer 36 may serve a number of purposes. For example, layer 36 may help to electrically insulate nanowires 34 from each other, which may be useful or essential for some applications. Layer 36 may also have desired optical properties (e.g., a desired index of refraction, which may be different from that of the nanowires). Layer 36 may provide additional structural support for nanowires 34, which may otherwise be more susceptible to breakage or damage from the environment or merely mechanically unstable. Accordingly, layer 36 may also serve to seal all or at least a portion of nanowires 34 off from the environment. This type of encapsulation technique may be useful when the nanowire structures are to be used in liquids or other potentially harsh environments during operation.

Layer 36 may be deposited using tools such as deposition tools 24 of FIG. 3. For example, layer 36 may be a silicon dioxide oxide layer that is deposited using a CVD tool from TEOS precursor or may be a spin-on glass layer or polymer layer that is spun onto or sprayed or evaporated onto substrate 10 and subsequently cured (e.g., using an oven or hotplate).

After the deposition or growth process that results in layer 36 has been completed, the nanowires 34 may be completely encapsulated in layer 36, as shown in FIG. 4e. With some deposition processes, gaps 37 may form in the deposited layer 36, which generally do not have an adverse impact on operation of device 12.

As shown in FIG. 4f, the tips 38 of nanowires 34 may be exposed by removing a portion of layer 36. In particular, the upper portion of layer 36 may be removed in the process of planarizing substrate 10, so that the tips 38 of nanowires 34 are located in the same plane as the planarized surface of the insulating material of layer 36 or protrude slightly out of the surface plane. Tools 30 of FIG. 3 may be used during planarization. Suitable planarization techniques that may be used include chemical-mechanical polishing, mechanical polishing, or wet or dry etching (e.g., reactive ion etching, laser trimming or etching, plasma etching, ion milling, chemical etching, combinations of such methods or other suitable techniques).

Device 12 of FIG. 4f may be packaged for use in an instrument or system (e.g., a chemical or biological detector or a computer display, etc.) If desired, the device 12 of FIG. 4f may be processed in subsequent processing steps to further configure device 12 for a particular application (e.g., for operation as a field emitter in a display or as a sensor site in a chemical or biological sensor). Subsequent processing may involve additional steps for metal and insulator and other material deposition and patterning, additional nanowire growth, etc.

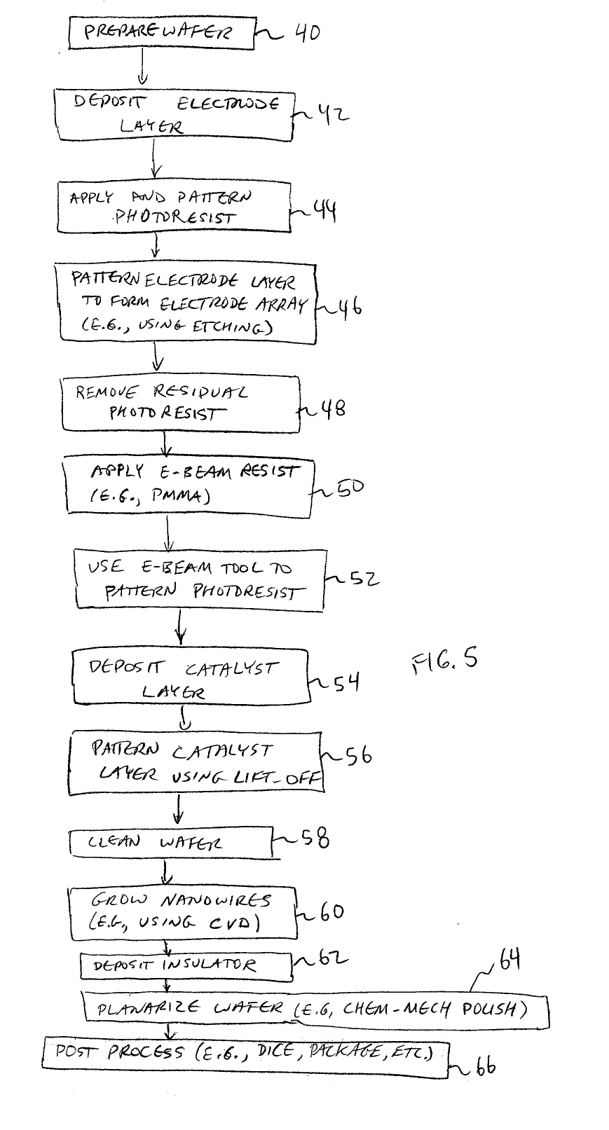

Illustrative steps involved in forming nanowire devices are shown in FIG. 5. In the illustrative embodiment of FIG. 5, a number of specific illustrative techniques are used. As described above, these are not the only possible techniques available, but merely serve as illustrative examples.

As step 40 of FIG. 5, substrate 10 may be prepared for processing. For example, a silicon wafer may be cleaned using standard cleaning techniques (e.g., a thermal oxide growth followed by a wet etch in hydrofluoric acid). An oxide or nitride or other suitable material layer may be formed on the cleaned wafer. For example, a thermal oxide may be grown or another suitable insulating layer may be formed on wafer 10. This ensures that subsequent metal patterns will not “short” one another through the substrate.

At step 42, a metal layer such as metal layer 32 of FIG. 4a may be deposited on substrate 10. For example, a layer of titanium, gold, molybdenum, chromium, or platinum, may be evaporated or sputtered onto substrate 10.

At step 44, a layer of photoresist may be applied to substrate 10 and patterned. The resist may, for example, be spun onto substrate 10 or sprayed onto substrate 10 and patterned using standard UV lithography techniques. The pattern formed by the photoresist may be used to define the shapes and spacing of electrodes 14 (FIG. 4b). At step 46, the electrode layer (metal layer 32 of FIG. 4a) may be patterned using wet or dry etching to form patterned electrodes 14.

Photoresist removal steps such as step 48 may be used whenever there is residual photoresist to remove from the substrate following an etch step or other patterning step.

To prepare substrate 10 for e-beam lithography, an e-beam resist such as polymethylmethacrylate (PMMA) may be applied to substrate 10 at step 50. An e-beam lithography tool may be used at step 52 to expose (pattern) the resist. Exposed areas of PMMA may be removed by e-beam irradiation. By exposing the relatively small areas of substrate 10 where it is desired to from catalyst sites 20, the process of step 52 ensures that there are openings in the PMMA layer that correspond to the pattern desired for sites 20. Typically the diameter or lateral dimension of each site 20 is on the order of a nanowire diameter. For example, if it is desired to grow carbon nanotubes of about 20 nm in diameter, the dimension of the openings in the PMMA that are defined by the e-beam tool will generally be on the order of about 20 nm.

Once the openings for the catalyst site pattern have been formed, the catalyst layer may be deposited at step 54. For example, a catalyst layer of nickel may be evaporated onto the substrate if it is desired to seed growth of carbon nanotubes. A catalyst layer of gold may be evaporated onto the substrate if it is desired to seed growth of silicon or germanium or other single-crystal nanowires.

The PMMA layer may be removed using the lift-off technique or other suitable resist removal technique at step 56, so that the only remaining catalyst is the catalyst in the desired catalyst sites 20.

At step 58 (and at other stages between process steps if desired), the substrate 10 may be cleaned (e.g., to remove residual photoresist.

At step 60, the nanowires may be grown using the techniques described in connection with using tools such as CVD tools 26 of FIG. 3. For example, thermal or plasma-enhanced CVD may be used to grow the nanowires.

At step 62, an insulator such as silicon oxide may be deposited on the nanowires (e.g., using a TEOS CVD process). Any suitable insulator may be deposited at step 62, including polymers, nitrides, glasses, etc.

At step 64, substrate 10 may be planarized (e.g., using a chemical-mechanical polishing technique).

At step 66, post processing steps may be performed if desired. For example, additional layers of material (e.g., metals, insulators, semiconductors) may be deposited and patterned). Additional nanowires may be grown. The devices 12 that have been formed on substrate 10 may be separated (e.g., by dicing wafer 10 into individual die or individual portions of substrate). Various packaging techniques may be used. For example, device 12 may be wire-bonded or connected with solder balls to a ceramic carrier, lead-frame or dual-inline package or other suitable mount or housing. Circuitry on other integrated or discreet circuits may be interconnected with device 12. Hermetic sealing may be used to protect portions of device 12 from the environment. After any desired post processing steps such as these are performed, device 12 may be installed in a system (e.g., in a sensor instrument or in a display, etc.)

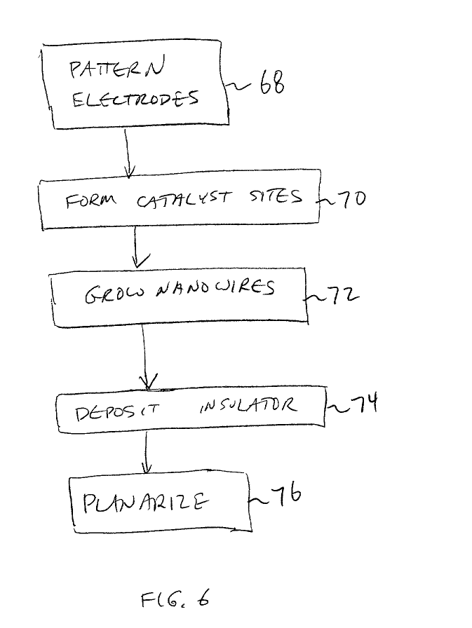

FIG. 6 is a more generalized flow chart showing illustrative steps involved in fabricating nanowire devices in accordance with the present invention. At step 68, electrodes 14 may be patterned. Any suitable techniques may be used for patterning electrodes 14. For example, a shadow mask may be used. As another example, a metal layer may be deposited and patterned using subsequent lithography steps and etching. If desired, the lift off process may be used. With the lift-off approach, patterned photoresist may be formed on substrate 10. A metal layer for electrodes 14 may be deposited on top of the patterned photoresist. The photoresist may then be removed.

At step 70, catalyst sites 20 may be formed on the patterned electrodes. Catalyst patterning techniques that may be used to form catalyst sites 20 include those based on heating deposited metal so that it collects into discrete metal areas (“metal migration“), heat-collapsible porous polymer balls filed with metal salts, techniques in which metal is evaporated through a thin film assembly of microscopic balls (e.g., balls 100 nm to 100 μm in diameter) that have been temporarily placed on the electrode surface, lithographic techniques (e.g., e-beam lithography, standard ultraviolet (UV) lithography, deep UV (DUV) lithography, extreme UV (EUV) lithography, etc.), X-ray or ion beam lithography, electrochemical deposition, electroless deposition, or soft lithography (e.g., when a damp “stamp” is used to impress a pattern of catalytic “link” on a substrate), etc.

At step 72, nanowires such as single-walled or multiple-walled carbon nanotubes, single-crystal semiconductor nanowires, carbon nanofibers (either solid rods or tubes with amorphous walls or graphitic cylindrical walls not perfectly parallel to the axis of the tube), metal nanowires (e.g., tungsten nanowires, molybdenum nanowires, etc.), and nanowires of inorganic compound materials (e.g., ZnO) may be grown from the catalyst sites. For example, thermal CVD or plasma CVD growth techniques may be used to grow nanowires. An electric field may be used during growth to enhance the uniformity of nanowire orientation.

A dielectric, insulator, or other suitable material may be deposited at step 74. Any suitable deposition or growth technique may be used. For example, silicon dioxide may be deposited using CVD from a TEOS precursor. Other dielectric materials that may be deposited or grown on the nanowires include polymers, glasses (e.g., spin-on glasses), nitride, and salts such as CaF₂. The additional material layer (or layers) formed on the nanowires may fill all or at least some of the volume between adjacent nanowires and may therefore help to increase the mechanical strength of the nanowires and electrically insulate the nanowires from each other. The additional material layer may also have desired optical properties (e.g., a desired index of refraction) and desired optoelectronic properties (e.g., a desired band gap).

At step 76, the devices 12 may be planarized. For example, chemical-mechanical polishing, mechanical polishing, or etching techniques may be used to planarize the oxide or other dielectric or insulating material deposited at step 74.

It will be understood that the foregoing is only illustrative of the principles of the invention and that various modifications can be made by those skilled in the art without departing from the scope and spirit of the invention. Many examples of such modifications have been given through the foregoing specification.

The invention claimed is:

1. A nanowire device comprising:
a substrate;
a plurality of corresponding patterned electrodes on the substrate;
a plurality of catalyst sites on each of the patterned electrodes;
a plurality of corresponding nanowires grown from the catalyst sites; and
a dielectric material deposited on the nanowires such that the dielectric material fills at least some volume between adjacent nanowires, enhances the strength of the nanowires, and provides electrical insulation between the nanowires, wherein the dielectric material is planarized to form a planarized surface at which tips of the nanowires are located.

2. The nanowire device defined in claim 1 wherein the nanowires comprise carbon nanotubes.

3. The nanowire device defined in claim 1 wherein the nanowires comprise single-crystal semiconductor nanowires.

4. The nanowire device defined in claim 1 wherein the dielectric material is silicon oxide.

5. The nanowire device defined in claim 1 wherein the substrate is silicon, wherein the dielectric material is chemically-mechanically polished silicon oxide, and wherein the nanowires are carbon nanotubes.

6. The nanowire device defined in claim 1 wherein the electrode pads have lateral dimensions in the range of 0.2-20 μm.

7. The nanowire device defined in claim 1 wherein there are at least nine electrodes in the device.

8. The nanowire device defined in claim 1 wherein at least some of the nanowires have diameters in the range of 10 nm to 100 nm.

9. The nanowire device defined in claim 1 wherein the substrate is silicon, the dielectric material includes silicon oxide, the nanowires comprise carbon nanotubes at least some of which have diameters in the range of 10 nm to 100 nm and lengths of more than 0.5 μm.

10. The nanowire device defined in claim 1 wherein the catalyst sites are arranged on the electrodes in a regular pattern.

11. A method for fabricating a nanowire device, comprising:
forming at least one metal electrode on a substrate;
depositing resist on the electrode;
patterning the resist using e-beam lithography to establish at least one hole that defines at least one catalyst site where catalyst is to be deposited;
depositing a layer of catalyst metal on top of the patterned resist and in the hole;
removing the patterned resist after depositing the layer of catalyst metal so that catalyst remains in the catalyst site defined by the hole; and
growing a nanowire from the catalyst site.

12. The method defined in claim 11 wherein the resist is patterned to establish a plurality of holes that define a plurality of catalyst sites from which a plurality of corresponding nanowires are grown, the method further comprising depositing an insulator on top of the nanowires.

13. The method defined in claim 11 wherein the resist is patterned to establish a plurality of holes that define a plurality of catalyst sites from which a plurality of corresponding nanowires are grown, the method further comprising depositing a layer of insulating material on top of the nanowires and planarizing the deposited material so that tips of the nanowires are exposed.

14. The method defined in claim 11 wherein the resist is patterned to establish a plurality of holes that define a plurality of catalyst sites from which a plurality of corresponding nanowires are grown, the method further comprising depositing a layer of insulator on top of the nanowires and planarizing the deposited insulator so that tips of the nanowires are exposed.

15. The method defined in claim 11 wherein the resist is patterned to establish a plurality of holes that define a plurality of catalyst sites from which a plurality of nanowires are grown, the method further comprising depositing a layer of silicon dioxide on top of the nanowires and planarizing the deposited oxide so that tips of the nanowires are exposed.

16. The method defined in claim 11 wherein forming at least one metal electrode on the substrate comprises forming a plurality of electrodes on the substrate.

17. The method defined in claim 11 wherein the substrate comprises a silicon wafer, wherein forming at least one metal electrode on the substrate comprises forming a plurality of electrodes on the substrate, wherein the resist is patterned to establish a plurality of holes on each electrode that define a plurality of catalyst sites from which a plurality of nanowires are grown, the method further comprising depositing a layer of insulator on top of the nanowires and planarizing the deposited insulator so that tips of the nanowires are exposed.

18. A method for forming a nanowire device comprising:
forming a plurality of metal electrodes on a substrate;
forming a plurality of catalyst sites on each electrode;
growing nanowires from the catalyst sites;
depositing a layer of dielectric on top of the nanowires; and
planarizing the dielectric after deposition so that tips of the nanowires are exposed.

19. The method defined in claim 18 wherein the metal electrodes include a metal selected from the group consisting of titanium, gold, and platinum, wherein the catalyst sites include a metal selected from the group consisting of nickel and gold, and wherein the substrate includes a material selected from the group consisting of silicon, quartz, sapphire, and glass.

20. The method defined in claim 18 wherein the nanowires comprise doped semiconductors.
